(19) United States
(12) Patent Application Publication
(10) Pub. No.: US 2023/0011400 A1
(43) Pub. Date: Jan. 12, 2023

(54) MEMS MICROPHONE

(71) Applicant: DB HITEK CO., LTD., Seoul (KR)

(72) Inventor: Kyu Hyun KWACK, Seoul (KR)

(21) Appl. No.: 17/810,107

(22) Filed: Jun. 30, 2022

(30) Foreign Application Priority Data
Jul. 6, 2021 (KR) 10-2021-0088307

(51) Int. Cl. H04R 19/04; H04R 1/08; H04R 7/04

(52) U.S. Cl. CPC H04R 19/04; H04R 1/08; H04R 7/04; H04R 2201/003

(57) ABSTRACT

A MEMS microphone includes a diaphragm disposed in a first direction, and an electrode structure disposed in the first direction and configured to surround the diaphragm and to be spaced apart from the diaphragm. The electrode structure includes electrodes spaced apart from each other in a second direction perpendicular to the first direction.

### CROSS-REFERENCE TO RELATED APPLICATION

This application claims the priority benefit of Korean Patent Application No. 10-2021-0088307, filed on Jul. 6, 2021, and all the benefits accruing therefrom under 35 U.S.C. § 119, the contents of which are incorporated by reference in their entirety.

### TECHNICAL FIELD

The present disclosure relates to a MEMS (Micro-Electro Mechanical System) microphone. More specifically, the present disclosure relates to a MEMS microphone capable of converting a sound into an acoustic signal using a diaphragm configured to be vibrated by sound pressure.

### BACKGROUND

A MEMS microphone may be used to convert a sound into an acoustic signal and may be manufactured by a MEMS technology. For example, the MEMS microphone may include a diaphragm disposed above a substrate and a back plate disposed above the diaphragm. The diaphragm and the back plate may be supported by a plurality of anchors on the substrate, and a predetermined air gap may be provided between the diaphragm and the back plate.

The diaphragm may include a lower conductive layer used as a lower electrode, and the back plate may include an insulating layer supported by the anchors and an upper conductive layer formed on the insulating layer. In this case, the upper conductive layer may be used as an upper electrode. The diaphragm may be vibrated by an applied sound pressure, whereby the air gap between the diaphragm and the back plate may be changed. Further, a capacitance between the diaphragm and the back plate may be changed by the change in the air gap, and the acoustic signal may be detected from the change in the capacitance.

However, when the back plate is deformed, for example, when sagging occurs in the back plate, the air gap may change, which may cause distortion in the sound signal. Further, because the acoustic signal detected from the diaphragm and the back plate is a single signal, it may be difficult to remove acoustic noise. Still further, when the back plate is disposed above the diaphragm as described above, the structure of the MEMS microphone may be relatively complicated, thereby increasing the manufacturing cost of the MEMS microphone.

### SUMMARY

The present disclosure provides a MEMS microphone having an improved structure in order to solve the above problems.

In accordance with an aspect of the present disclosure, a MEMS microphone may include a diaphragm disposed in a first direction, and an electrode structure disposed in the first direction and configured to surround the diaphragm and to be spaced apart from the diaphragm. Particularly, the electrode structure may include electrodes spaced apart from each other in a second direction perpendicular to the first direction.

In accordance with some embodiments of the present disclosure, the electrode structure may include a first electrode disposed at a first height lower than the diaphragm, and a second electrode disposed at a second height higher than the diaphragm.

In accordance with some embodiments of the present disclosure, the electrode structure may include a first electrode disposed at a first height, and a second electrode disposed at a second height higher than the first height. In such cases, the diaphragm may be disposed at the first height.

In accordance with some embodiments of the present disclosure, the electrode structure may include a first electrode disposed at a first height, a second electrode disposed at a second height higher than the first height, and a third electrode disposed at a third height higher than the second height. In such cases, the diaphragm may be disposed at the second height.

In accordance with some embodiments of the present disclosure, the diaphragm may include a plurality of first protrusions protruding toward the electrode structure, the electrode structure may include a plurality of second protrusions protruding toward the diaphragm, and the first protrusions may be disposed among the second protrusions.

In accordance with some embodiments of the present disclosure, the MEMS microphone may further include support members connecting the diaphragm and the electrode structure and elastically supporting the diaphragm.

In accordance with some embodiments of the present disclosure, the electrode structure may further include insulating layers for electrically insulating the electrodes from each other, and the support members may be disposed between the insulating layers.

In accordance with some embodiments of the present disclosure, each of the support members may include a first support portion disposed between the insulating layers, and a second support portion connecting the first support portion and the diaphragm.

In accordance with some embodiments of the present disclosure, the second support portion may have a serpentine shape.

In accordance with some embodiments of the present disclosure, the support members may be made of the same material as the diaphragm.

In accordance with some embodiments of the present disclosure, the diaphragm may be made of the same material as the electrodes.

In accordance with another aspect of the present disclosure, a MEMS microphone may include a substrate having a cavity formed therethrough, a diaphragm disposed above the cavity to be parallel to the substrate, an electrode structure disposed on the substrate and configured to surround the diaphragm and to be spaced apart from the diaphragm, and support members connecting the diaphragm and the electrode structure and elastically supporting the diaphragm. Particularly, the electrode structure may include electrodes spaced apart from each other in a direction perpendicular to the substrate, and insulating layers for electrically insulating the substrate and the electrodes with one another.

In accordance with some embodiments of the present disclosure, the electrode structure may include a first electrode disposed at a first height lower than the diaphragm, and a second electrode disposed at a second height higher than the diaphragm.

In accordance with some embodiments of the present disclosure, the electrode structure may include a first insulating layer formed on the substrate, a first electrode formed on the first insulating layer, a second insulating layer formed on the first electrode, a third insulating layer formed on the second insulating layer, and a second electrode formed on the third insulating layer. In such cases, the support members may be disposed between the second insulating layer and the third insulating layer.

In accordance with some embodiments of the present disclosure, the electrode structure may include a first electrode disposed at a first height from the substrate, and a second electrode disposed at a second height higher than the first height. In such cases, the diaphragm may be disposed at the first height.

In accordance with some embodiments of the present disclosure, the electrode structure may include a first insulating layer formed on the substrate, first electrodes formed on the first insulating layer, a second insulating layer formed on the first insulating layer and the first electrodes, and a second electrode formed on the second insulating layer. In such cases, the support members may be disposed between the first electrodes and may be electrically insulated from the first electrodes and the second electrode by the second insulating layer.

In accordance with some embodiments of the present disclosure, the electrode structure may include a first electrode disposed at a first height from the substrate, a second electrode disposed at a second height higher than the first height, and a third electrode disposed at a third height higher than the second height. In such cases, the diaphragm may be disposed at the second height.

In accordance with some embodiments of the present disclosure, the electrode structure may include a first insulating layer formed on the substrate, a first electrode formed on the first insulating layer, a second insulating layer formed on the first electrode, second electrodes formed on the second insulating layer, a third insulating layer formed on the second insulating layer and the second electrodes, and a third electrode formed on the third insulating layer. In such cases, the support members may be disposed between the second electrodes and may be electrically insulated from the second electrodes and the third electrode by the third insulating layer.

In accordance with some embodiments of the present disclosure, each of the support members may include a first support portion disposed between the insulating layers, and a second support portion connecting the first support portion and the diaphragm.

In accordance with some embodiments of the present disclosure, the support members may be made of the same material as the diaphragm.

In accordance with the embodiments of the present disclosure as described above, the back plate used in the prior art may be removed, thereby solving the problem of distortion in the acoustic signal that may be caused by the deformation of the back plate. Further, a plurality of signals may be detected from the diaphragm and the electrodes, and the acoustic signal may be obtained from the plurality of signals, thereby reducing noise of the acoustic signal. Still further, the MEMS microphone including the diaphragm and the electrode structure may have a relatively simple structure compared to the prior art, and accordingly, the manufacturing cost of the MEMS microphone may be significantly reduced.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic plan view illustrating a MEMS microphone in accordance with an embodiment of the present disclosure;

FIG. 2 is a schematic cross-sectional view taken along a line A-A′ as shown in FIG. 1;

FIG. 3 is a schematic cross-sectional view taken along a line B-B′ as shown in FIG. 1;

FIG. 4 is a schematic plan view illustrating another example of support members as shown in FIG. 1;

FIG. 5 is a schematic plan view illustrating a MEMS microphone in accordance with another embodiment of the present disclosure;

FIG. 6 is a schematic cross-sectional view taken along a line C-C′ as shown in FIG. 5;

FIG. 7 is a schematic cross-sectional view taken along a line D-D′ as shown in FIG. 5;

FIG. 8 is a schematic plan view illustrating a diaphragm and support members as shown in FIG. 7;

FIG. 9 is a schematic plan view illustrating a MEMS microphone in accordance with still another embodiment of the present disclosure;

FIG. 10 is a schematic cross-sectional view taken along a line E-E′ as shown in FIG. 9;

FIG. 11 is a schematic cross-sectional view taken along a line F-F′ as shown in FIG. 9; and

FIG. 12 is a schematic plan view illustrating a diaphragm and support members as shown in FIG. 11.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings and include the deviations of the forms. The areas may be entirely schematic, and their forms may not describe or depict accurate forms or structures in any given area and are not intended to limit the scope of the present invention.

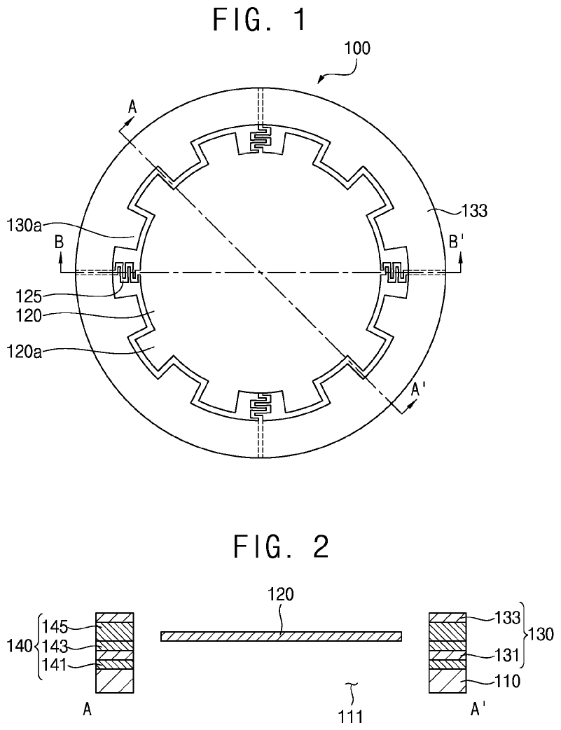

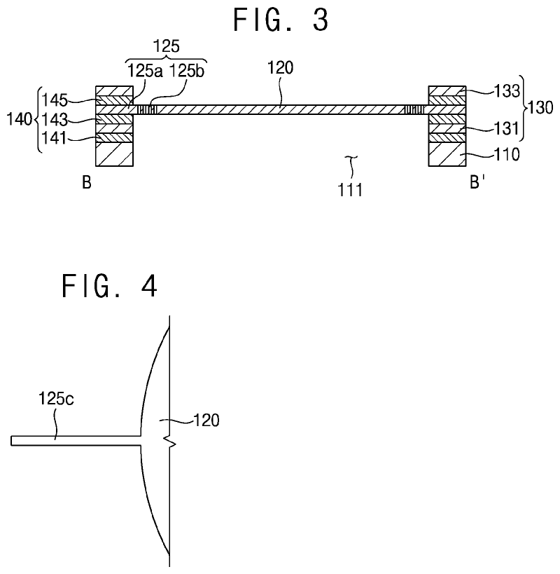

FIG. 1 is a schematic plan view illustrating a MEMS microphone in accordance with an embodiment of the present disclosure, FIG. 2 is a schematic cross-sectional view taken along a line A-A′ as shown in FIG. 1, FIG. 3 is a schematic cross-sectional view taken along a line B-B′ as shown in FIG. 1, and FIG. 4 is a schematic plan view illustrating another example of support members as shown in FIG. 1.

Referring to FIGS. 1 to 4, a MEMS microphone 100, in accordance with an embodiment of the present disclosure, may include a diaphragm 120 disposed in a first direction, and an electrode structure 130 disposed in the first direction and configured to surround the diaphragm 120 and to be spaced apart from the diaphragm 120.

For example, the diaphragm 120 may be disposed above a substrate 110 to be parallel to the substrate 110, and the electrode structure 130 may be disposed on the substrate 110 to surround the diaphragm 120. A silicon wafer may be used as the substrate 110, and the electrode structure 130 may have a ring shape surrounding the diaphragm 120. The substrate 110 may have a cavity 111 corresponding to the diaphragm 120. The cavity 111 may be formed through the substrate 110, and the diaphragm 120 may be exposed through the cavity 111.

The electrode structure 130 may include electrodes 131 and 133 spaced apart from each other in a second direction perpendicular to the first direction. Specifically, the electrode structure 130 may include electrodes 131 and 133 spaced apart from each other in a direction perpendicular to the substrate 110, and insulating layers 140 for electrically insulating the substrate 110 and the electrodes 131 and 133 with one another.

Further, the MEMS microphone 100 may include a plurality of support members 125 for supporting the diaphragm 120. For example, the support members 125 may connect between the diaphragm 120 and the electrode structure 130 and may elastically support the diaphragm 120 so that the diaphragm 120 is vibrated by an applied sound pressure. In particular, the support members 125 may be disposed between the insulating layers 140 and may be electrically insulated from the electrodes 131 and 133 by the insulating layers 140.

In accordance with an embodiment of the present disclosure, the electrode structure 130 may include a first electrode 131 disposed at a first height lower than the diaphragm 120, and a second electrode 133 disposed at a second height higher than the diaphragm 120. Specifically, the electrode structure 130 may include a first insulating layer 141 formed on the substrate 110, a first electrode 131 formed on the first insulating layer 141, a second insulating layer 143 formed on the first electrode 131, a third insulating layer 145 formed on the second insulating layer 143, and a second electrode 133 formed on the third insulating layer 145. In such cases, the support members 125 may be disposed between the second insulating layer 143 and the third insulating layer 145.

For example, the first insulating layer 141 may be made of an insulating material such as silicon oxide and may have a first opening for exposing the diaphragm 120. The first electrode 131 may be made of a conductive material such as polysilicon doped with impurities and may have a second opening for exposing the diaphragm 120. The second insulating layer 143 may be made of an insulating material such as silicon oxide and may have a third opening for exposing the diaphragm 120.

The support members 125 may be formed on the second insulating layer 143 and may be connected to edge portions of the diaphragm 120. For example, each of the support members 125 may include a first support portion 125a formed on the second insulating layer 143, and a second support portion 125b connecting the first support portion 125a and the diaphragm 120. In particular, the diaphragm 120 and the second support portions 125b of the support members 125 may be exposed by the cavity 111 and the first, second, and third openings.

The third insulating layer 145 may be formed on the second insulating layer 143 and the support members 125. In particular, the third insulating layer 145 may be formed on the second insulating layer 143 and the first support portions 125a. In addition, the third insulating layer 145 may be made of an insulating material such as silicon oxide and may have a fourth opening for exposing the diaphragm 120 and the second support portions 125b.

The second electrode 133 may be made of a conductive material such as polysilicon doped with impurities and may have a fifth opening for exposing the diaphragm 120 and the second support portions 125b. The diaphragm 120 and the support members 125 may be formed of a conductive material such as polysilicon doped with impurities.

Although not shown in figures, the MEMS microphone 100 may include a first bonding pad electrically connected to the first electrode 131, a second bonding pad electrically connected to the diaphragm 120, and a third bonding pad electrically connected to the second electrode 133.

In accordance with an embodiment of the present disclosure, when the diaphragm 120 is vibrated by the sound pressure, a capacitance between the first electrode 131 and the diaphragm 120 may change, and thus, a first signal may be detected between the first electrode 131 and the diaphragm 120. Further, a capacitance between the second electrode 133 and the diaphragm 120 may change, and thus, a second signal may be detected between the second electrode 133 and the diaphragm 120. In such cases, a phase of the second signal may be opposite to that of the first signal, and thus, after inverting the phase of the second signal, the phase-inverted second signal may be merged with the first signal in order to remove noise from the first signal and the second signal. As a result, the MEMS microphone 100 may generate an acoustic signal from which the noise is sufficiently removed from the first and second signals.

In accordance with an embodiment of the present disclosure, in order to make the amplitudes of the first signal and the second signal equal to each other, a height difference between the first electrode 131 and the diaphragm 120 may be the same as a height difference between the diaphragm 120 and the second electrode 133, whereby the noise may be sufficiently removed from the first signal and the second signal.

Further, the diaphragm 120 may include a plurality of first protrusions 120a protruding toward the electrode structure 130, and the electrode structure 130 may include a plurality of second protrusions 130a protruding toward the diaphragm 120. In such cases, the first protrusions 120a may be disposed among the second protrusions 130a, and thus, the capacitance between the first electrode 131 and the diaphragm 120 and the capacitance between the diaphragm 120 and the second electrode 133 may increase. As a result, the amplitudes of the first signal and the second signal may be increased and, accordingly, the sensitivity of the MEMS microphone 100 may be improved.

Still further, in order to facilitate the vibration of the diaphragm 120, each of the second support portions 125b may have a serpentine shape, and thus the sensitivity of the MEMS microphone 100 may be improved. Alternatively, as shown in FIG. 4, beam-shaped support members 125c may be used to support the diaphragm 120. In this case, a thickness and a width of the support members 125c may be appropriately adjusted to improve the sensitivity of the MEMS microphone 100.

Hereinafter, a method of manufacturing the MEMS microphone 100 will be described.

A first insulating layer 141 may be formed on a substrate 110 by a deposition process, and a first conductive layer may be formed on the first insulating layer 141 by a deposition process. The first insulating layer 141 may be made of an insulating material such as silicon oxide and the first conductive layer may be made of polysilicon doped with impurities. The first conductive layer may be patterned to have a second opening by a photolithography process and an etching process, whereby a first electrode 131 may be formed on the first insulating layer 141.

A second insulating layer 143 may be formed on the first insulating layer 141 and the first electrode 131 by a deposition process. The second insulating layer 143 may be made of an insulating material such as silicon oxide. The second insulating layer 143 may be planarized through a planarization process such as a chemical mechanical polishing (CMP) process, and a second conductive layer may be formed on the second insulating layer 143 by a deposition process. The second conductive layer may be patterned by a photolithography process and an etching process, whereby a diaphragm 120 and support members 125 may be simultaneously formed on the second insulating layer 143. The second conductive layer may be made of polysilicon doped with impurities.

A third insulating layer 145 may be formed on the second insulating layer 143, the diaphragm 120, and the support members 125 by a deposition process, and then, the third insulating layer 145 may be planarized by a planarization process such as a CMP process. Further, a third conductive layer may be formed on the third insulating layer 145 by a deposition process. The third insulating layer 145 may be made of an insulating material such as silicon oxide, and the third conductive layer may be made of polysilicon doped with impurities.

The third conductive layer may be patterned to have a fifth opening by a photolithography process and an etching process, whereby a second electrode 133 may be formed on the third insulating layer 145. The third insulating layer 145 may be partially removed to have a fourth opening by an etching process. In this case, the diaphragm 120 and the second support portions 125b of the support members 125 may be exposed by the fourth opening and the fifth opening. Further, the fourth opening and the fifth opening may be formed such that the diaphragm 120 is spaced apart from the electrode structure 130.

Then, a back grinding process may be performed to reduce a thickness of the substrate 110 and a cavity 111 may be formed to correspond to the diaphragm 120 through the substrate 110 by a photolithography process and an etching process. Further, the first insulating layer 141 and the second insulating layer 143 may be partially removed to have a first opening and a third opening, respectively, whereby the diaphragm 120 and the second support portions 125b of the support members 125 may be exposed by the cavity 111 and the first, second, and third openings. In addition, the first, second, and third openings may be formed such that the diaphragm 120 is spaced apart from the electrode structure 130.

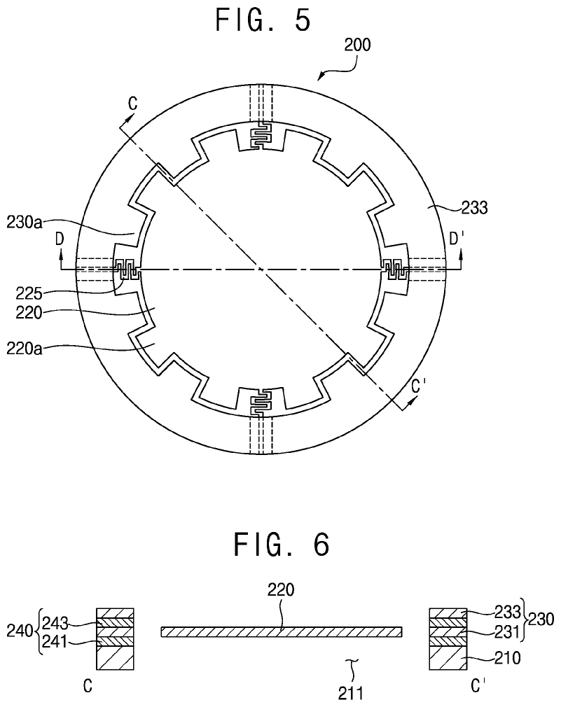

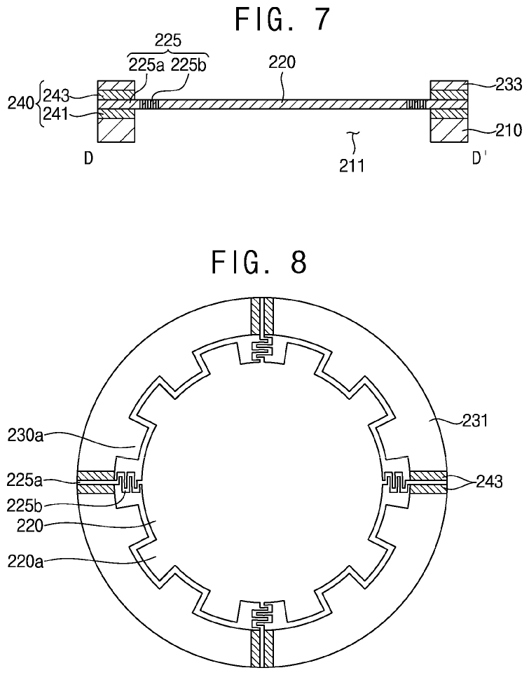

FIG. 5 is a schematic plan view illustrating a MEMS microphone in accordance with another embodiment of the present disclosure, FIG. 6 is a schematic cross-sectional view taken along a line C-C′ as shown in FIG. 5, FIG. 7 is a schematic cross-sectional view taken along a line D-D′ as shown in FIG. 5, and FIG. 8 is a schematic plan view illustrating a diaphragm and support members as shown in FIG. 7.

Referring to FIGS. 5 to 8, a MEMS microphone 200, in accordance with another embodiment of the present disclosure, may include a diaphragm 220 disposed in a first direction, and an electrode structure 230 disposed in the first direction and configured to surround the diaphragm 220 and to be spaced apart from the diaphragm 220.

For example, the diaphragm 220 may be disposed above a substrate 210 to be parallel to the substrate 210, and the electrode structure 230 may be disposed on the substrate 210 to surround the diaphragm 220. A silicon wafer may be used as the substrate 210 and the electrode structure 230 may have a ring shape surrounding the diaphragm 220. The substrate 210 may have a cavity 211 corresponding to the diaphragm 220. The cavity 211 may be formed through the substrate 210 and the diaphragm 220 may be exposed through the cavity 211.

The electrode structure 230 may include electrodes 231 and 233 spaced apart from each other in a second direction perpendicular to the first direction. Specifically, the electrode structure 230 may include electrodes 231 and 233 spaced apart from each other in a direction perpendicular to the substrate 210 and insulating layers 240 for electrically insulating the substrate 210 and the electrodes 231 and 233 with one another.

Further, the MEMS microphone 200 may include a plurality of support members 225 for supporting the diaphragm 220. For example, the support members 225 may connect between the diaphragm 220 and the electrode structure 230 and may elastically support the diaphragm 220 so that the diaphragm 220 is vibrated by an applied sound pressure. In particular, the support members 225 may be disposed between the insulating layers 240 and may be electrically insulated from the electrodes 231 and 233 by the insulating layers 240.

In accordance with another embodiment of the present disclosure, the electrode structure 230 may include a first electrode 231 disposed at a first height from the substrate 210, and a second electrode 233 disposed at a second height higher than the first height. Specifically, the electrode structure 230 may include a first insulating layer 241 formed on the substrate 210, first electrodes 231 formed on the first insulating layer 241, a second insulating layer 243 formed on the first insulating layer 241 and the first electrodes 231, and a second electrode 233 formed on the second insulating layer 243. In such cases, the support members 225 may be disposed between the first electrodes 231, and may be electrically insulated from the first electrodes 231 and the second electrode 233 by the second insulating layer 243.

In embodiments, the first insulating layer 241 may be made of an insulating material such as silicon oxide. The first electrodes 231 may be made of a conductive material such as polysilicon doped with impurities, and may be formed to surround the diaphragm 220. As shown in figures, the MEMS microphone 200 includes four first electrodes 231 (as depicted for each quadrant in FIG. 8). However, the number of the first electrodes 231 may be changed and the scope of the present invention will not be limited thereby. In embodiments, after forming a first conductive layer on the first insulating layer 241, the first conductive layer may be patterned, whereby the first electrodes 231, the diaphragm 220, and the support members 225 may be simultaneously formed on the first insulating layer 241. As a result, the diaphragm 220 may be disposed at the same height as the first electrodes 231.

Each of the support members 225 may include a first support portion 225a formed on the first insulating layer 241, and a second support portion 225b connecting the first support portion 225a and the diaphragm 220. In this case, the first support portions 225a of the support members 225 may be disposed between the first electrodes 231.

After forming the diaphragm 220, the support members 225 and the first electrodes 231, a second insulating layer 243 may be formed on the first insulating layer 241, the diaphragm 220, the support members 225 and the first electrodes 231. In particular, the second insulating layer 243 may be made of an insulating material such as silicon oxide and may be formed to fill spaces between the support members 225 and the first electrodes 231. Further, the second insulating layer 243 may be formed to fill spaces between the diaphragm 220 and the first electrodes 231. Alternatively, a planarization process such as a CMP process may be performed after the second insulating layer 243 is formed.

After forming the second insulating layer 243, a second conductive layer may be formed on the second insulating layer 243. For example, the second conductive layer may be made of polysilicon doped with impurities. Then, the second conductive layer may be patterned to have a third opening, whereby a second electrode 233 may be formed on the second insulating layer 243. Further, the second insulating layer 243 may be partially removed to have a second opening. In this case, the second opening and the third opening may be formed such that the diaphragm 220 and the second support portions 225b of the support members 225 are exposed and the electrode structure 230 is spaced apart from the diaphragm 220.

After forming the second electrode 233 as described above, a back grinding process may be performed to reduce a thickness of the substrate 210 and a photolithography process and an anisotropic etching process may be performed to form a cavity 211.

Further, the first insulating layer 241 may be partially removed by an anisotropic etching process in order to form a first opening. In particular, the first opening may be formed such that the diaphragm 220 and the second support portions 225b of the support members 225 are exposed and the electrode structure 230 is spaced apart from the diaphragm 220. As a result, the diaphragm 220 and the second support portions 225b of the support members 225 may be exposed by the cavity 211 and the first opening.

In accordance with another embodiment of the present disclosure, the diaphragm 220 may include a plurality of first protrusions 220a protruding toward the electrode structure 230, and the electrode structure 230 may include a plurality of second protrusions 230a protruding toward the diaphragm 220. In such cases, the first protrusions 220a may be disposed among the second protrusions 230a. Further, in order to facilitate the vibration of the diaphragm 220, each of the second support portions 225b may have a serpentine shape. Accordingly, the sensitivity of the MEMS microphone 200 may be improved.

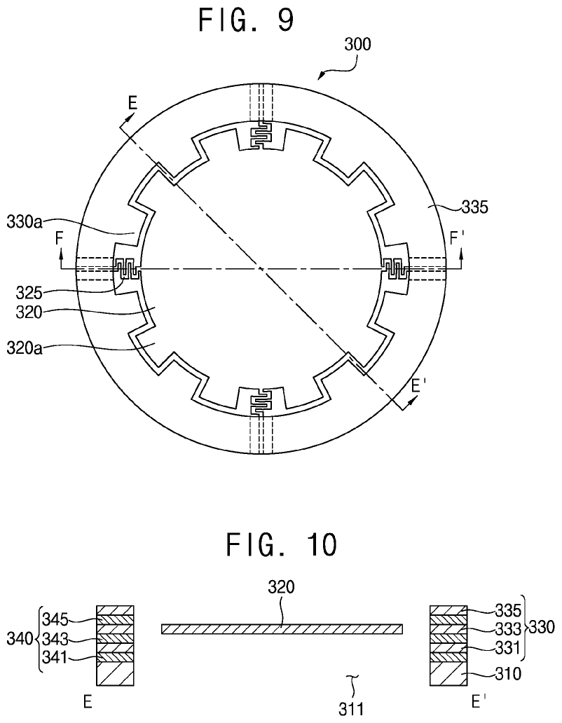

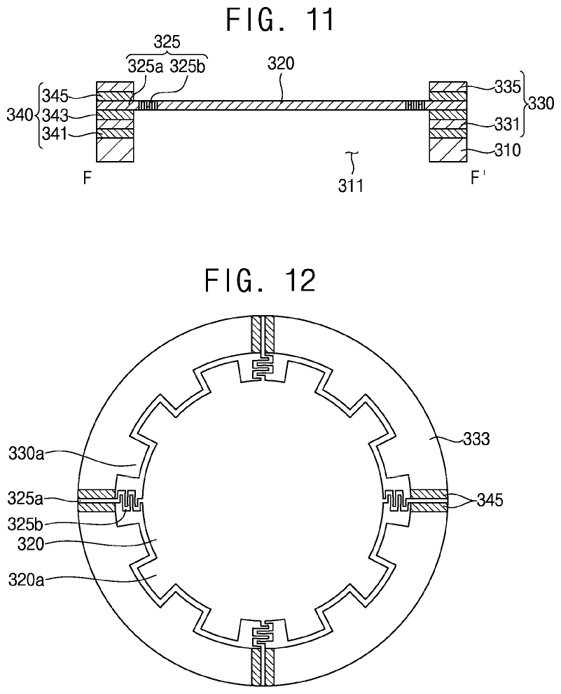

FIG. 9 is a schematic plan view illustrating a MEMS microphone in accordance with still another embodiment of the present disclosure, FIG. 10 is a schematic cross-sectional view taken along a line E-E′ as shown in FIG. 9, FIG. 11 is a schematic cross-sectional view taken along a line F-F′ as shown in FIG. 9, and FIG. 12 is a schematic plan view illustrating a diaphragm and support members as shown in FIG. 11.

Referring to FIGS. 9 to 12, a MEMS microphone 300, in accordance with still another embodiment of the present disclosure, may include a diaphragm 320 disposed in a first direction, and an electrode structure 330 disposed in the first direction and configured to surround the diaphragm 320 and to be spaced apart from the diaphragm 320.

For example, the diaphragm 320 may be disposed above a substrate 310 to be parallel to the substrate 310 and the electrode structure 330 may be disposed on the substrate 310 to surround the diaphragm 320. A silicon wafer may be used as the substrate 310 and the electrode structure 330 may have a ring shape surrounding the diaphragm 320. The substrate 310 may have a cavity 311 corresponding to the diaphragm 320. The cavity 311 may be formed through the substrate 310 and the diaphragm 320 may be exposed through the cavity 311.

The electrode structure 330 may include electrodes 331, 333 and 335 spaced apart from each other in a second direction perpendicular to the first direction. Specifically, the electrode structure 330 may include electrodes 331, 333 and 335 spaced apart from each other in a direction perpendicular to the substrate 310 and insulating layers 340 for electrically insulating the substrate 310 and the electrodes 331, 333 and 335 with one another.

Further, the MEMS microphone 300 may include a plurality of support members 325 for supporting the diaphragm 320. For example, the support members 325 may connect between the diaphragm 320 and the electrode structure 330 and may elastically support the diaphragm 320 so that the diaphragm 320 is vibrated by an applied sound pressure. In particular, the support members 325 may be disposed between the insulating layers 340 and may be electrically insulated from the electrodes 331, 333 and 335 by the insulating layers 340.

In accordance with still another embodiment of the present disclosure, the electrode structure 330 may include a first electrode 331 disposed at a first height from the substrate 310, a second electrode 333 disposed at a second height higher than the first height, and a third electrode 335 disposed at a third height higher than the second height. In such cases, the diaphragm 320 may be disposed at the second height. Specifically, the electrode structure 330 may include a first insulating layer 341 formed on the substrate 310, a first electrode 331 formed on the first insulating layer 341, a second insulating layer 343 formed on the first electrode 331, second electrodes 333 formed on the second insulating layer 343, a third insulating layer 345 formed on the second insulating layer 343 and the second electrodes 333, and a third electrode 335 formed on the third insulating layer 345. In such cases, the support members 325 may be disposed between the second electrodes 333 and may be electrically insulated from the second electrodes 333 and the third electrode 335 by the third insulating layer 345.

For example, the first insulating layer 341 may be made of an insulating material such as silicon oxide, and the first electrode 331 may be made of a conductive material such as polysilicon doped with impurities. After the first insulating layer 341 is formed on the substrate 310, a first conductive layer may be formed on the first insulating layer 341. Subsequently, the first conductive layer may be patterned to have a second opening, whereby the first electrode 331 may be formed on the first insulating layer 341.

After the first electrode 331 is formed, a second insulating layer 343 may be formed on the first insulating layer 341 and the first electrode 331. The second insulating layer 343 may be made of an insulating material such as silicon oxide. Alternatively, after forming the second insulating layer 343, a planarization process such as a CMP process may be performed.

The second electrodes 333 may be made of a conductive material such as polysilicon doped with impurities and may be formed to surround the diaphragm 320. As shown in figures, the MEMS microphone 300 includes four second electrodes 333 (as depicted in each quadrant in FIG. 12). However, the number of the second electrodes 333 may be changed, and the scope of the present invention will not be limited thereby. For example, after a second conductive layer is formed on the second insulating layer 343, the second conductive layer may be patterned, whereby the second electrodes 333, the diaphragm 320, and the support members 325 may be simultaneously formed on the second insulating layer 343. As a result, the diaphragm 320 may be disposed at the same height as the second electrodes 333.

Each of the support members 325 may include a first support portion 325a formed on the second insulating layer 343, and a second support portion 325b connecting the first support portion 325a and the diaphragm 320. In this case, the first support portions 325a of the support members 325 may be disposed between the second electrodes 333.

After forming the diaphragm 320, the support members 325 and the second electrodes 333, the third insulating layer 345 may be formed on the second insulating layer 343, the diaphragm 320, the support members 325, and the second electrodes 333. In particular, the third insulating layer 345 may be made of an insulating material such as silicon oxide, and may be formed to fill spaces between the support members 325 and the second electrodes 333. Further, the third insulating layer 345 may be formed to fill spaces between the diaphragm 320 and the second electrodes 333. Alternatively, after forming the third insulating layer 345, a planarization process such as a CMP process may be performed.

After the third insulating layer 345 is formed, a third conductive layer may be formed on the third insulating layer 345. For example, the third conductive layer may be made of polysilicon doped with impurities. Subsequently, the third conductive layer may be patterned to have a fifth opening, whereby the third electrode 335 may be formed on the third insulating layer 345. Further, the third insulating layer 345 may be partially removed by an etching process to have a fourth opening. In this case, the fourth opening and the fifth opening may be formed so that the diaphragm 320 and the second support portions 325b of the support members 325 are exposed and the electrode structure 330 is spaced apart from the diaphragm 320.

After forming the third electrode 335 as described above, a back grinding process may be performed to reduce a thickness of the substrate 310, and a photolithography process and an anisotropic etching process may be performed to form a cavity 311.

Further, the first insulating layer 341 and the second insulating layer 343 may be partially removed by an anisotropic etching process in order to form a first opening and a second opening, respectively. In particular, the first, second and third openings may be formed such that the diaphragm 320 and the second support portions 325b of the support members 325 are exposed and the electrode structure 330 is spaced apart from the diaphragm 320. As a result, the diaphragm 320 and the second support portions 325b of the support members 325 may be exposed by the cavity 311 and the first, second and third openings.

In accordance with still another embodiment of the present disclosure, the diaphragm 320 may include a plurality of first protrusions 320a protruding toward the electrode structure 330, and the electrode structure 330 may include a plurality of second protrusions 330a protruding toward the diaphragm 320. In such cases, the first protrusions 320a may be disposed among the second protrusions 330a. Further, in order to facilitate the vibration of the diaphragm 320, each of the second support portions 325b may have a serpentine shape. Accordingly, the sensitivity of the MEMS microphone 300 may be improved.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

What is claimed is:

1. A MEMS (micro-electro mechanical system) microphone comprising:
a diaphragm disposed in a first direction; and
an electrode structure disposed in the first direction and configured to surround the diaphragm and to be spaced apart from the diaphragm,
wherein the electrode structure comprises a plurality of electrodes spaced apart from each other in a second direction perpendicular to the first direction.

2. The MEMS microphone of claim 1, wherein the electrode structure comprises:
a first electrode disposed at a first height lower than the diaphragm; and
a second electrode disposed at a second height higher than the diaphragm.

3. The MEMS microphone of claim 1, wherein the electrode structure comprises:
a first electrode disposed at a first height; and
a second electrode disposed at a second height higher than the first height,
wherein the diaphragm is disposed at the first height.

4. The MEMS microphone of claim 1, wherein the electrode structure comprises:
a first electrode disposed at a first height;
a second electrode disposed at a second height higher than the first height; and
a third electrode disposed at a third height higher than the second height,
wherein the diaphragm is disposed at the second height.

5. The MEMS microphone of claim 1, wherein the diaphragm comprises a plurality of first protrusions protruding toward the electrode structure;
the electrode structure comprises a plurality of second protrusions protruding toward the diaphragm; and
the first protrusions are disposed among the second protrusions.

6. The MEMS microphone of claim 1, further comprising:
support members connecting the diaphragm and the electrode structure and elastically supporting the diaphragm.

7. The MEMS microphone of claim 6, wherein the electrode structure further comprises insulating layers for electrically insulating the electrodes from each other; and
the support members are disposed between the insulating layers.

8. The MEMS microphone of claim 7, wherein each of the support members comprises:
a first support portion disposed between the insulating layers; and
a second support portion connecting the first support portion and the diaphragm.

9. The MEMS microphone of claim 8, wherein the second support portion has a serpentine shape.

10. The MEMS microphone of claim 6, wherein the support members are made of a same material as the diaphragm.

11. The MEMS microphone of claim 1, wherein the diaphragm is made of a same material as the electrodes.

12. A MEMS (micro-electro mechanical system) microphone comprising:
a substrate having a cavity formed therethrough;
a diaphragm disposed above the cavity to be parallel to the substrate;
an electrode structure disposed on the substrate and configured to surround the diaphragm and to be spaced apart from the diaphragm; and
support members connecting the diaphragm and the electrode structure and elastically supporting the diaphragm,
wherein the electrode structure comprises:
a plurality of electrodes spaced apart from each other in a direction perpendicular to the substrate; and
a plurality of insulating layers for electrically insulating the substrate and the plurality of electrodes with one another.

13. The MEMS microphone of claim 12, wherein the electrode structure comprises:
a first electrode disposed at a first height lower than the diaphragm; and
a second electrode disposed at a second height higher than the diaphragm.

14. The MEMS microphone of claim 12, wherein the electrode structure comprises:
a first insulating layer formed on the substrate;
a first electrode formed on the first insulating layer;
a second insulating layer formed on the first electrode;
a third insulating layer formed on the second insulating layer; and
a second electrode formed on the third insulating layer,
wherein the support members are disposed between the second insulating layer and the third insulating layer.

15. The MEMS microphone of claim 12, wherein the electrode structure comprises:
a first electrode disposed at a first height from the substrate; and
a second electrode disposed at a second height higher than the first height,
wherein the diaphragm is disposed at the first height.

16. The MEMS microphone of claim 12, wherein the electrode structure comprises:
a first insulating layer formed on the substrate;
first electrodes formed on the first insulating layer;
a second insulating layer formed on the first insulating layer and the first electrodes; and
a second electrode formed on the second insulating layer,
wherein the support members are disposed between the first electrodes and are electrically insulated from the first electrodes and the second electrode by the second insulating layer.

17. The MEMS microphone of claim 12, wherein the electrode structure comprises:
a first electrode disposed at a first height from the substrate;
a second electrode disposed at a second height higher than the first height; and
a third electrode disposed at a third height higher than the second height,
wherein the diaphragm is disposed at the second height.

18. The MEMS microphone of claim 12, wherein the electrode structure comprises:
a first insulating layer formed on the substrate;
a first electrode formed on the first insulating layer;
a second insulating layer formed on the first electrode;
second electrodes formed on the second insulating layer;
a third insulating layer formed on the second insulating layer and the second electrodes; and
a third electrode formed on the third insulating layer,
wherein the support members are disposed between the second electrodes and are electrically insulated from the second electrodes and the third electrode by the third insulating layer.

19. The MEMS microphone of claim 12, wherein each of the support members comprises:
a first support portion disposed between the insulating layers; and
a second support portion connecting the first support portion and the diaphragm.

20. The MEMS microphone of claim 12, wherein the support members are made of a same material as the diaphragm.
